(19) United States
(12) Patent Application Publication
(10) Pub. No.: US 2007/0023795 A1
(43) Pub. Date: Feb. 1, 2007

(54) Semiconductor device and method of fabricating the same

(75) Inventors: Hajime Nagano, Yokkaichi (JP); Atsushi Yagishita, Yokohama (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/486,004

(22) Filed: Jul. 14, 2006

(30) Foreign Application Priority Data
Jul. 15, 2005 (JP) 2005-206618
Oct. 4, 2005 (JP) 2005-291233
Nov. 17, 2005 (JP) 2005-333010

(51) Int. Cl. H01L 29/76; H01L 21/336

(52) U.S. Cl. 257/288; 438/197

(57) ABSTRACT

A semiconductor device includes a metal oxide semiconductor (MOS) transistor including two source/drain regions located at a surface layer side of the semiconductor substrate, a stress-inducing film formed so as to cover the source/drain region of the MOS transistor, the stress-inducing film applying stress to a channel region formed between the source/drain regions and having an opening corresponding to an electrical connection region of the source/drain regions, the opening having a first dimension with respect to a propagation direction of a charge carrier moving within the channel region of the MOS transistor and a second dimension with respect to a direction perpendicular to the propagation direction of the MOS transistor, the first dimension being larger than the second dimension.

### CROSS-REFERENCE TO RELATED APPLICATIONS

This application is based upon and claims the benefit of priority from the prior Japanese Patent Application Nos. 2005-206618, filed on Jul. 15, 2005, 2005-291233, filed on Oct. 4, 2005, and 2005-333010, filed on Nov. 17, 2005, the entire contents of which are incorporated herein by reference.

### BACKGROUND OF THE INVENTION

1. Field of the Invention

The present invention relates to a semiconductor device provided with a metal oxide semiconductor (MOS) transistor configured so that stress is applied to a channel region, and a method of fabricating the same.

2. Description of the Related Art

A semiconductor has a characteristic that the mobility of carriers changes when subjected to stress. It has been proposed to utilize this characteristic for the purpose of improvement in a response speed of a device. More specifically, in MOS transistors, a device is configured so that stress is applied to a channel region in order to increase the mobility of carriers.

The following describes a method of applying stress to the channel region. Firstly, a gate electrode and a source/drain region of a MOS transistor are covered with a stress-inducing film such as silicon nitride film, so that stress is applied to the channel region. JP-A-2002-198368 discloses such a method. The method is also disclosed by Scott E. Thompson et al., “A 90-nm Logic Technology Featuring Strained-Silicon,” IEEE TRANSACTIONS ON ELECTRON DEVICES, Vol. 51, No. 11, November 2004, pp 1790-1797. Consequently, since the mobility of carriers in the channel region is improved, an operating characteristic of the MOS transistor can be improved.

In the foregoing configuration, however, contact holes need to be formed in the stress-inducing film when contact plugs and the like are formed in the source/drain regions. The effect of the stress is reduced as the result of formation of the contact holes in the stress-inducing film, whereupon the mobility of the carriers is reduced. In the same way, also when the stress-inducing film is formed so as to cover the gate electrode of the MOS transistor, via holes are formed in order that a via plug may be connected onto the gate electrode. In this case, too, the mobility of the carriers is reduced.

Secondly, stress is applied to a channel region at a semiconductor substrate side in another configuration. For example, the configuration is disclosed by Gannavaram, S., Pesovic, N. and Ozturk, C., “Low Temperature (800° C.) Recessed Junction Selective Silicon-Germanium Source/Drain Technology for sub-70 nm CMOS,” Electron Devices Meeting, 2000, IEDM Technical Digest International, 2000, p. 437-440. In this method, a gate insulating film and gate electrode are formed on a semiconductor substrate and thereafter, a layer applying stress to a channel is formed on an end of the channel and the gate electrode so that the channel is subjected to stress thereby to be strained. In this case, stress can be applied to the channel region of the semiconductor substrate from the source/drain regions at both sides of the channel. Consequently, lateral strain is applied to the channel such that the mobility of carriers can be improved.

However, the above-described configuration has the following drawback. A gate electrode is formed in a surface layer of the channel region or a region beneath the gate electrode. Accordingly, it is difficult to produce strain even when stress is applied to the region. Characteristics of a semiconductor device can be improved most effectively when the mobility of carriers is improved in the surface layer of the channel region. Accordingly, in order that a desired strain may be produced, a thickness of each of the source/drain regions needs to be increased so that larger stress can be applied to the region. In this case, however, strain becomes excessively large in some part of the region. The excessively large strain results in occurrence of cracks in the region or renders production of smaller devices difficult.

Thirdly, stress is applied to the channel region from an insulation-isolated part. For example, JP-A-2004-235332 discloses one of such methods as follows. In the disclosed method, the shallow trench isolation (STI) structure for element isolation of a MOS transistor employs a configuration of applying stress to the channel region.

However, when the stress applied to the channel region is increased for obtainment of further larger mobility of carriers, the stress to which the channel region is subjected strains the semiconductor substrate to a larger degree. Consequently, there is a possibility that the semiconductor substrate may crack in some cases. Furthermore, in addition to the drawback in the fabrication of semiconductor devices, there is a possibility that electrical characteristics of the semiconductor devices may adversely affected by the stress.

### SUMMARY OF THE INVENTION

Therefore, an object of the present invention is to provide a semiconductor device in which formation of contact holes or the like can be carried out without deterioration in the characteristics of the elements or devices when the entire MOS transistor is covered with a stress-inducing film for the purpose of improving operating speeds of the elements by improving the mobility of carriers in the channel region of the MOS transistor.

Another object of the invention is to provide a semiconductor device in which the mobility of carriers can be improved in the surface layer of the channel region when stress is applied to the channel region at the semiconductor substrate side, and a method of fabricating the same.

Further another object of the invention is to provide a semiconductor device in which the mobility of carriers can be improved so that the characteristics of the elements can be improved, while stress applied to an element formation region can be prevented from being excessive and a method of fabricating the same.

In one aspect, the present invention provides a semiconductor device comprising, a semiconductor substrate having a surface layer, a metal oxide semiconductor (MOS) transistor provided with two source/drain regions located at the surface layer side of the semiconductor substrate, and a stress-inducing film formed so as to cover the source/drain regions of the MOS transistor, the stress-inducing film applying stress to a channel region formed between the source/drain regions and having an opening corresponding to an electrical connection region of the source/drain regions, the opening having a first dimension with respect to a propagation direction of carriers moving within the channel region of the MOS transistor and a second dimension with respect to a direction perpendicular to the propagation direction of the MOS transistor, the first dimension being larger than the second dimension.

The invention also provides a semiconductor device comprising a semiconductor substrate, a channel region formed on the semiconductor substrate and having an upper surface, two source/drain regions formed on the semiconductor substrate with the channel region being interposed therebetween, each source/drain region being made from a semiconductor material having a lattice constant differing from the semiconductor substrate, and a gate insulating film and a gate electrode each formed on the upper surface of the channel region, wherein the channel region is distributed so that strain due to stress the channel region receives from the source/drain region is largest at the surface side of the semiconductor substrate and becomes smaller in a direction of depth of the channel region.

In another aspect, the present invention provides a method of fabricating a semiconductor device, comprising removing portions of a semiconductor substrate corresponding to source/drain regions to be formed at both sides of a channel region respectively, burying a semiconductor material in portions resulting from removal of the portions corresponding to the source/drain regions, the semiconductor material having a lattice constant differing from the semiconductor substrate, and forming a gate insulating film and a gate electrode on a surface of the channel forming region of the semiconductor substrate.

The invention further provides a semiconductor device comprising a semiconductor substrate, an element formation region formed on the semiconductor substrate so as to include a channel region serving as a propagation path of a carrier, and a gate electrode formed on a gate insulating film further formed on the channel region, wherein the element formation region is formed so that the channel region receives, from an outer periphery of the element formation region, a tensile stress in a direction perpendicular to the propagation path of the carrier and a compressive stress in a direction of the propagation path.

The invention further provides a method of fabricating a semiconductor device, comprising forming a first trench in first sides of a semiconductor substrate opposed to each other with an element formation region being interposed therebetween, burying a first insulating film in the first trench, the first insulating film applying tensile stress to the element formation region, forming a second trench in second sides of the semiconductor substrate opposed to each other with the element formation region being interposed therebetween, burying a second insulating film in the second trench, the second insulating film applying compressive stress to the element formation region, forming a channel region and source/drain regions so that a direction in which the element formation region receives compressive stress from the second trench is identical with a direction of propagation path of a carrier, and forming a gate electrode on a gate insulating film formed on an upper part of the channel region.

### BRIEF DESCRIPTION OF THE DRAWINGS

Other objects, features and advantages of the present invention will become clear upon reviewing the following description of the embodiment with reference to the accompanying drawings, in which:

FIGS. 1A and 1B are sectional and top views of a semiconductor device in accordance with a first embodiment of the invention;

FIG. 2 is a graph showing a ratio of amount of strain to an opening width in X direction of stress-inducing film, the ratio being obtained from an experiment;

FIGS. 3A and 3B are views similar to FIGS. 1A and 1B, showing a second embodiment of the invention, respectively;

FIG. 4 is schematic sectional view of a third embodiment in accordance with the invention;

FIGS. 5A to 5H are schematic sectional views of the semiconductor device at a stage of the fabricating process;

FIG. 6 is a graph showing stress distribution in the direction of depth of the channel region;

FIG. 7 is a view similar to FIG. 6, showing the case where a dummy gate is remaining;

FIGS. 8A to 8D are a schematic plan view and sectional views of a fourth embodiment in accordance with the invention;

FIGS. 9A to 9D are views similar to FIGS. 8A to 8D in the fourth embodiment respectively;

FIGS. 10A to 10D are also views similar to FIGS. 8A to 8D, showing another stage, respectively;

FIGS. 11A to 11D are also views similar to FIGS. 8A to 8D, showing further another stage, respectively;

FIGS. 12A to 12D are also views similar to FIGS. 8A to 8D, showing further another stage, respectively;

FIGS. 13A to 13D are also views similar to FIGS. 8A to 8D, showing further another stage, respectively;

FIGS. 14A to 14D are also views similar to FIGS. 8A to 8D, showing further another stage, respectively;

FIGS. 15A and 15B are schematic external views for explaining stresses of n-MOSFET and p-MOSFET respectively;

FIG. 16 is a graph showing dependency of tensile stress of an eighth insulating film upon annealing temperature; and

FIG. 17 is a graph showing dependency of tensile stress of a second insulating film upon annealing temperature.

### DETAILED DESCRIPTION OF THE INVENTION

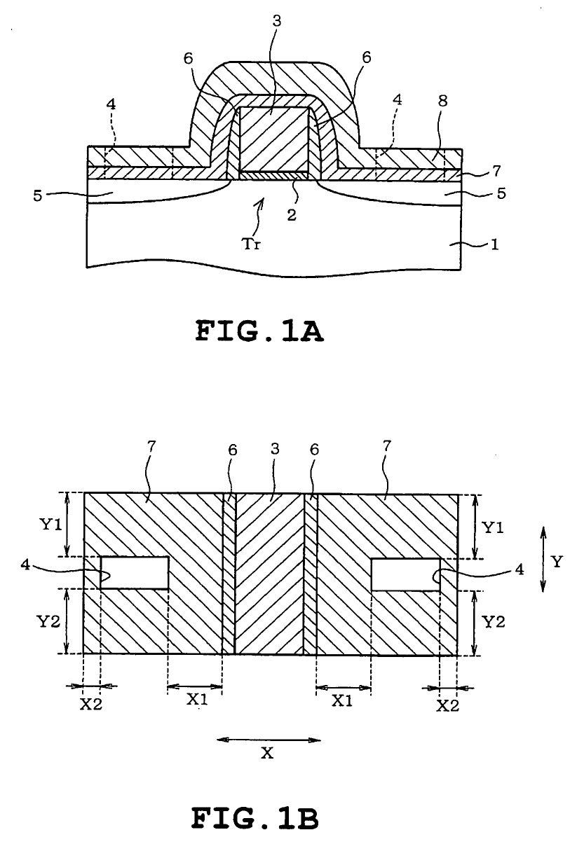

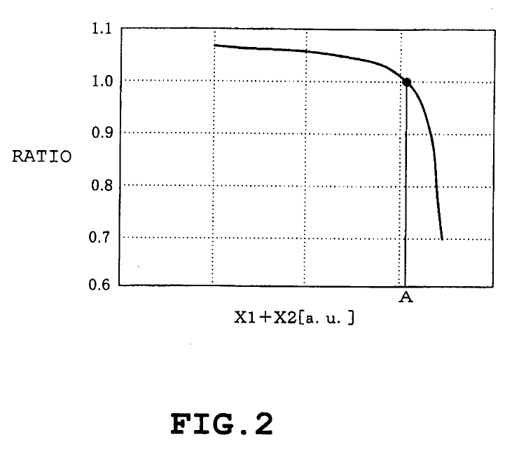

A first embodiment of the semiconductor device in accordance with the present invention will be described with reference to FIGS. 1A to 2. FIGS. 1A and 1B illustrate structures of longitudinal and transverse sections of an n-channel MOS transistor Tr respectively. The n-channel MOS transistor Tr comprises a p-type silicon substrate 1 serving as a semiconductor substrate and a gate insulating film 2 formed on the substrate 1 and a gate electrode 3 further formed on the gate insulating film 2. Two source/drain regions 5 are formed by doping portions of the substrate 1 corresponding to opposite sides of the gate electrode 3 with impurities terminals. The gate insulating film 2 is a silicon oxide film formed by thermal oxidation of a surface of the silicon substrate 1, for example. The gate electrode 3 is formed by depositing metal silicide layers on a polycrystalline silicon layer doped with impurities, for example. The gate electrode 3 has sidewalls on which respective gate sidewall insulating films 6 are formed.

A stress-inducing film 7 is formed so as to cover upper surfaces of the source/drain region 5, the gate electrode 3 and the gate sidewall insulating film 6. The stress-inducing film 7 is formed, for example, by a silicon nitride film and stores inside stress produced when the temperature of the film at the time of film formation returns to a normal temperature, thereby applying stress to a substrate. The stress-inducing film 7 is formed with an opening 4 serving as a contact hole. The opening 4 is provided for forming a contact plug electrically connecting the source/drain regions 5 and upper layer wiring (not shown) to each other.

The opening 4 is formed into a rectangular shape which is elongated in an X direction or in a direction between the source region 5 and drain region 5, or more specifically, in a direction parallel to a direction in which carrier waves are propagated, as shown in FIG. 1B. A Y direction is perpendicular to the X direction. Although the opening 4 is formed into a rectangular shape in the embodiment, the opening 4 may be formed into an elliptic shape, instead. When the opening 4 is elliptic in shape, it is desirable that the opening 4 is formed so that a long axis of the ellipsoid substantially corresponds with the X direction (the direction in which carriers propagate).

FIG. 2 shows changes in the magnitude of stress due to the stress-inducing film 7 according to a shape of the opening 4. In this case, the Y axis designates a ratio of a first amount of strain to a second amount of strain. The first amount of strain is obtained when the opening 4 is square in shape on condition that an area of the opening 4 is constant. The second amount of strain is obtained when the dimension in the X direction is changed on condition that an area of the opening 4 is constant. In this case, in order to be shown as a dimension of the stress-inducing film 7 in the source/drain region 5, the dimension in the X direction is presented as a sum of the dimensions X1 and X2 of a portion except for the opening 4. The dimension in the Y direction is set in the same manner as described above.

In FIG. 2, the opening 4 is square when the X axis takes the value of A. When the dimension (X1+X2) in the X direction is located on the left of point A, the dimension in the X direction is larger than the dimension in the Y direction. On the other hand, when the dimension (X1+X2) in the X direction is located on the right of point A, the dimension in the X direction is smaller than the dimension in the Y direction. Measurement of an amount of strain was carried out by a known stress profile measurement method. As a result of the above-described conditions, when the dimension (X1+X2) in the X direction is rendered longer and the dimension (Y1+Y2) in the Y direction is rendered shorter, or more specifically, when the dimension of the opening 4 in the X direction is rendered shorter and the dimension of the opening 4 in the Y direction is rendered longer, an amount of strain allowed to be applied to the channel region tends to be rapidly reduced relative to an amount of strain in the case of a square opening 4.

Furthermore, when the dimension (X1+X2) in the X direction is rendered shorter and the dimension (Y1+Y2) in the Y direction is rendered longer, a predetermined or more amount of strain can be obtained in the direction of propagation of carrier waves in the channel region as compared with the case where the opening 4 is a square window. More specifically, larger stress can be applied to the channel region when the opening 4 is set so as to be elongate in the direction of propagation of carriers. Additionally, in the case where the opening 4 has an elliptic shape, larger stress can also be applied to the channel region when a longer axis is set so as to be elongate in the direction in parallel to the X direction.

In the first embodiment, the contact opening 4 formed in the stress inducing film 7 is set so as to be longer in the X direction (the direction of propagation of carriers) as compared with the case where the opening 4 is longer in the Y direction (the direction perpendicular to the direction of propagation of carriers). Accordingly, larger stress can be applied to the channel region in the embodiment as compared with the case where the opening is square or circular, for example. Consequently, the mobility of the carrier waves in the channel region can be improved even when the openings 4 are formed.

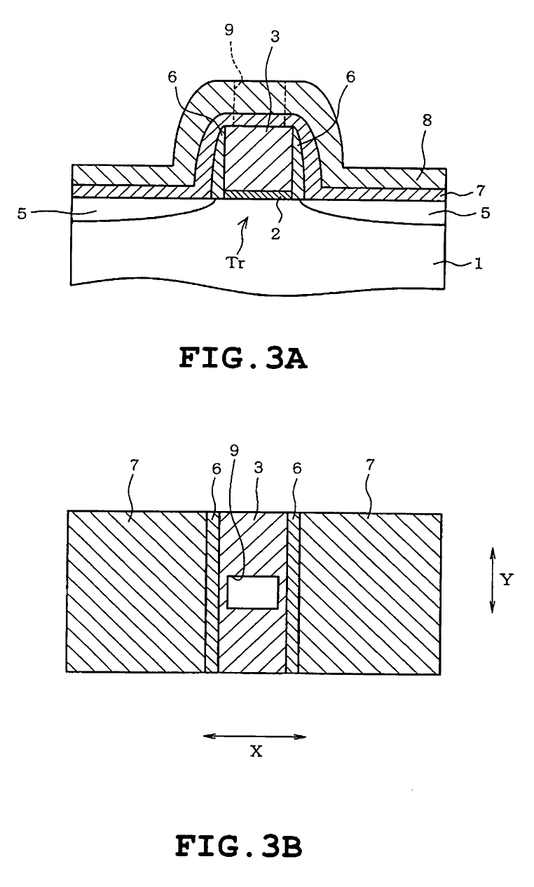

FIGS. 3A and 3B illustrate a second embodiment of the invention. The second embodiment differs from the first embodiment in that the gate electrode 3 is formed with a contact via hole (opening) 9 when the stress inducing film 7 is formed over the gate electrode 3.

When stress is applied to the channel region by the stress inducing film 7 formed over the gate electrode 3, too, the opening 9 is shaped so that the dimension of the opening 9 in the X direction (the direction in which the carriers propagate) is rendered longer and the width or the dimension in the Y direction is rendered shorter, in the same manner as in the first embodiment. Consequently, a large amount of strain can be applied to the channel region and accordingly, the opening 9 can be formed without reduction in the mobility of the carriers.

The invention is applied to the n-channel MOS transistor Tr in the foregoing embodiments. However, the invention should not be limited to the foregoing embodiments. The invention may be applied to a p-channel MOS transistor, instead. In this case, directions of stress externally applied to the channel region of the p-channel MOS transistor are opposite to each other. However, it is desirable to form the opening 4 so that the opening 4 is elongate in the direction of propagation of the carriers.

In order that the mobility of holes may be improved in the channel region in the case of the p-channel MOS transistor, it is desirable to form a silicon nitride film over the source/drain regions so that a compressive stress is applied to the channel region. The description of the fabricating method will be eliminated since the method has no direct relation to the features of the embodiment. However, JP-A-2003-273240 discloses an applicable fabricating method.

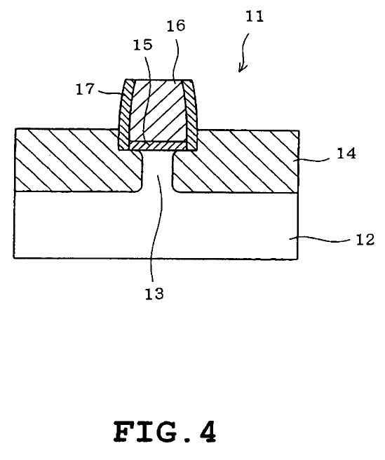

FIGS. 4 to 7 illustrate a third embodiment of the invention. In the third embodiment, stress is applied to the channel region from the semiconductor substrate side. FIG. 4 is a typical schematic section of a p-channel MOS transistor 11. A silicon substrate 12 serving as the semiconductor substrate is provided with the channel region 13 and the source/drain regions 14 which are formed at both sides of the channel region 13 so as to sandwich the region. Each source/drain region 14 is formed by selective epitaxial growth of silicon germanium (SiGe) but not a silicon layer. SiGe crystal has a larger lattice constant than silicon. Due to difference in the lattice constant, the channel region 13 which is a part of the silicon substrate is subjected to stress from the source/drain regions 14 thereby to strain.

A gate insulating film 15 comprising a silicon oxide film is formed over the channel region 13 and has a predetermined film thickness. A gate electrode 16 comprising a silicon oxide film is formed on the gate insulating film 15. The gate electrode 16 has a larger width than the channel region 13 and includes both sides projecting to the respective source/drain regions 14. Furthermore, the gate electrode 16 is formed so that an upper part thereof has a smaller width than a side thereof in contact with the gate insulating film 15 as will be described later in the fabricating process. Silicon nitride films 17 are formed on the sidewalls of the gate electrode 16. Each silicon nitride film 17 has a predetermined film thickness and provides electrical insulation between the gate electrode 16 and the source/drain regions 14.

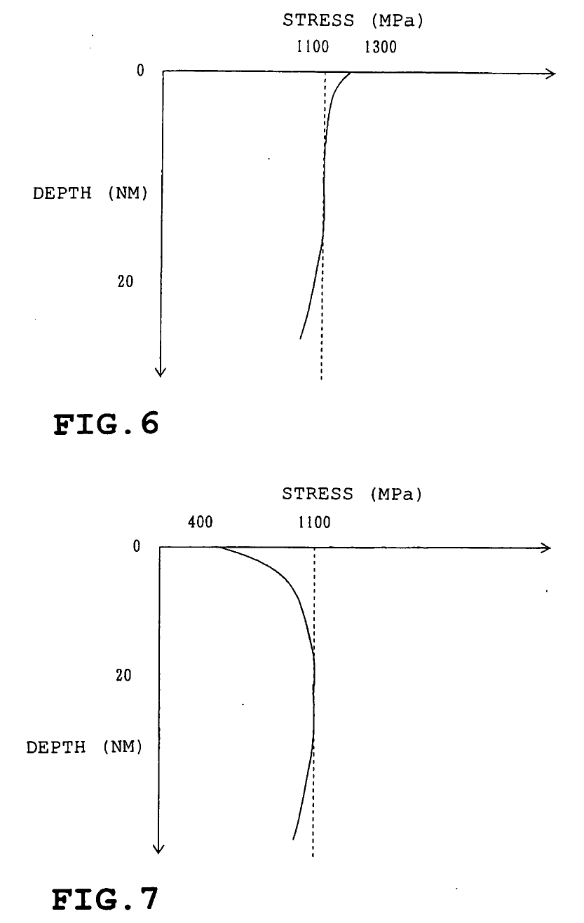

SiGe crystal which will be formed into source/drain regions 14 are formed and thereafter, an upper part of the channel region 13 is once exposed as will be described later. Subsequently, the gate insulating film 15, gate electrode 16 and silicon nitride film 17 are formed thereafter. Accordingly, the channel region 13 is subjected to a compressive stress from the source/drain regions 14 of SiGe crystal, thereby being caused to strain. In this case, a surface layer is caused to strain to a largest degree. This results in an increase in the mobility of carriers of the silicon substrate 12 or the channel region 13 comprised of silicon monocrystal as compared with the case where no strain is applied to the channel region and accordingly, an operating speed is improved. In this case, the stress to which the channel region 13 is subjected is distributed, for example, as shown in FIG. 6 on the basis of measurement by the inventors. The axis of abscissas designates a depth (nm) from a surface of the channel region 13 and the axis of ordinates designates magnitude of stress applied to the channel region 13 (NPa). As obvious from FIG. 6, the stress is highest in the surface layer and takes the value of 1.3 GPa. Furthermore, the stress is 1.1 GPa in a middle part of the channel region 13, which value is substantially as large as the value of the surface layer. As the depth is increased, the silicon substrate 12 at the bottom side causes stress relaxation, whereupon the magnitude of stress is reduced.

Consequently, another measurement about equivalent to conventional configuration indicates that most noticeable results are achieved in the surface layer of the channel region. More specifically, in the configuration that the gate electrode has previously been made from SiGe, a part corresponding to the source/drain regions is later made from SiGe. Even in this case, stress is relaxed in the surface layer of the channel region since the previously made gate electrode is present. Even when compared with internal stress, the stress in the surface layer is smaller.

Thus, when the MOS transistor 11 is configured as described above, the distribution of stress applied to the channel region 13 in the direction of depth can be suppressed. As a result, an amount of strain can be increased in a part serving as a channel in the surface layer where a largest amount of carrier (hole) flows, as compared with conventional configurations. Consequently, the mobility of carrier (hole) can be improved even though the concentration of Ge is the same as in the conventional configurations or the structure of the channel region is the same as in the conventional configurations.

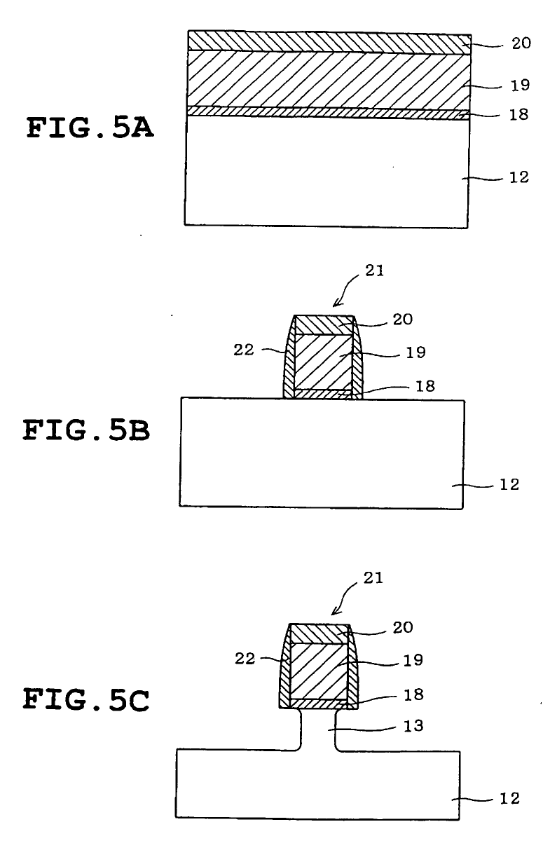

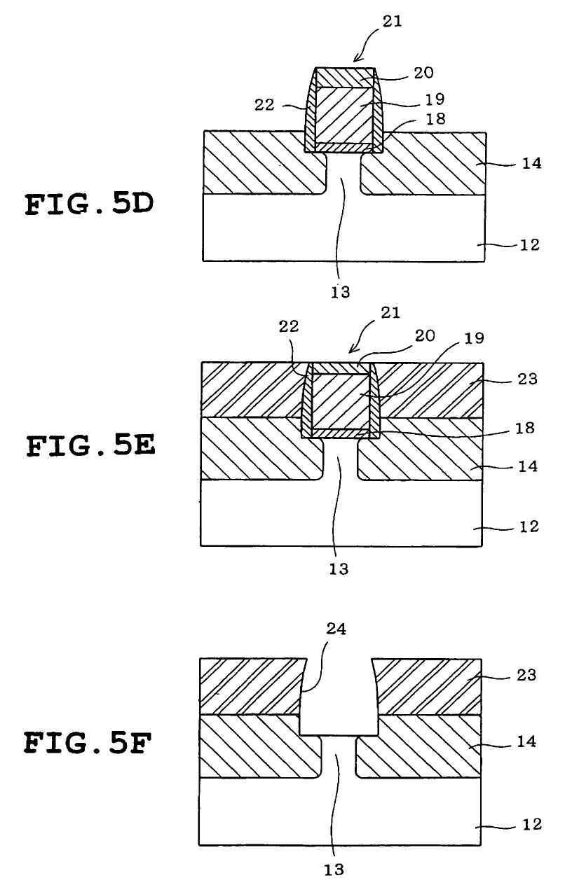

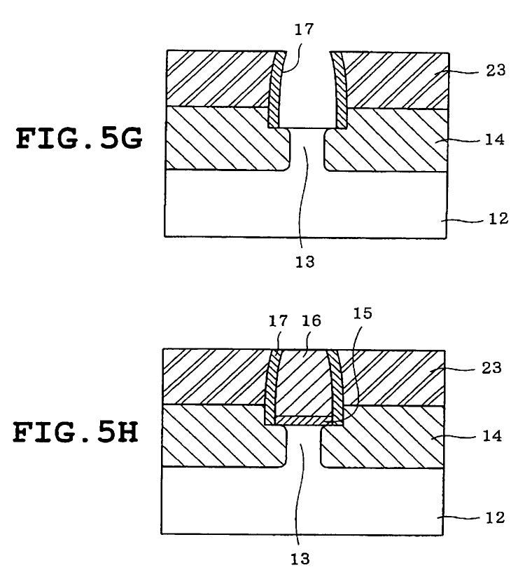

A fabricating process for obtaining the above MOS transistor will now be described with reference to FIGS. 5A to 5H. Firstly, as shown in FIG. 5A, a silicon oxide film 18 is formed on an upper surface of the silicon substrate 12 serving as the semiconductor substrate so as to have a film thickness ranging from 5 to 50 nm. A polycrystalline silicon film 19 is deposited on an upper surface of the silicon oxide film 18, and a silicon nitride film 20 is formed on an upper surface of the polycrystalline silicon film 19. Subsequently, a photolithography process is carried out to apply and pattern a resist. An etching process is then carried out so that parts of the films 18, 19 and 20 corresponding to a gate electrode remain unetched, whereby a dummy gate 21 is formed. Silicon nitride films 22 serving as protective films are formed on sides of the dummy gate 21 respectively as shown in FIG. 5B. In this case, the silicon nitride film is formed on a whole side of the dummy gate 21. Thereafter, an anisotropic etching is carried out so that the silicon nitride films 22 remains on the sides of the dummy gate 21. A silicon oxide film may be formed instead of the silicon nitride film 22.

Subsequently, an etching process is carried out so that parts of the silicon substrate 12 corresponding to the source/drain regions 14 are removed as shown in FIG. 5C. In this case, the etching process may be an ion etching process, a solution etching process or an etching process employing a hydrochloric acid gas. The dummy gate 21 serves as a mask for leaving the channel region 13 behind. Subsequently, a SiGe crystal is selectively formed on the aforesaid parts of the silicon substrate 12 corresponding to the source/drain regions 14 respectively as shown in FIG. 5D. Ge has a concentration ranging from 10 to 30% and a film thickness which is on the basis of the upper surface of the substrate and ranges from 0 to 50 nm. FIG. 7 shows the distribution of stress applied to the channel region 13. As obvious from FIG. 7, stress is distributed in the direction of depth. Stress is at about 400 MPa in a part beneath the silicon nitride film 13. A maximum of 1.1 GPa is reached at the depth of about 20 nm from the silicon oxide film 18.

Subsequently, a tetraethyl Orthosilicate (TEOS) film 23 is formed substantially on the whole surface of the silicon oxide film 18 so as to have a film thickness of about 100 nm. Successively, a chemical mechanical polishing (CMP) process is carried out until the silicon nitride film 20 is exposed, whereby a state as shown in FIG. 5E is obtained. The silicon nitride film 20 over the gate electrode 19 is removed by a phosphoric acid solution. Furthermore, the polycrystalline silicone film 19 constituting the dummy gate 21 is removed. Successively, the silicon nitride films 22 remaining on the respective sidewalls are removed, and the silicon oxide film 18 remaining on the bottom is also removed. A recess 24 for forming a gate electrode is then formed, so that a state as shown in FIG. 5F is obtained. In this case, the recess 24 has a smallest width at the opening thereof, and the width is gradually increased toward the depth. Furthermore, in the state as shown in FIG. 5F, stress applied to the channel region 13 is distributed as described above with reference to FIG. 6. More specifically, there is a difference in the stress in the direction of depth. The stress is at 1.3 GPa on the surface of the silicon substrate 12 and is gradually reduced flatly as the depth is increased.

Subsequently, a silicon nitride film 17 is formed on the whole surface. The silicon nitride film 17 is then processed by a reactive ion etching (RIE) process so as to cover sidewalls of the SiGe layers forming the source/drain regions 14. Thereafter, an oxide film on the surface of the silicon substrate 12 is removed by a solution containing diluted hydrofluoric acid. An oxidation treatment is carried out again so that a gate insulating film 15 is formed on the surface of the channel region 13 of the silicon substrate 12. Thereafter, the CMP process is carried out so that the polycrystalline silicon film other than the gate forming portion is removed, whereupon a state as shown in FIG. 5H is obtained. An etching process is carried out with the use of a solution to remove the TEOS film 24, whereby the structure as shown in FIG. 4 is obtained.

The above-described fabricating method can achieve the following effects. SiGe is selectively formed on the source/drain regions 14 at both sides of the channel region 13, so that stress is applied to the channel region 13. The dummy gate 21 formed over the channel region 13 is once removed so that repulsive force the dummy gate applies to the channel region 13 is canceled. Consequently, the surface layer of the channel region 13 can produce a largest amount of strain. Furthermore, even when a largest strain is applied to the surface layer of the channel region 13, a SiGe layer applying the similar stress to that in the conventional configuration may be formed. As a result, unnecessary stress can be prevented from being applied to the channel region 13.

The invention should not be limited to the foregoing embodiment. The embodiment may be modified or expanded as follows. In the third embodiment, the mobility of the holes as carriers is improved in order that the compressive stress may be applied to the channel region 13. However, the source/drain regions 14 may be made from a material applying tensile stress to the channel region, such as silicon carbide (SiC). In this case, a largest strain can be applied to the surface layer of the channel region 13, whereupon the mobility of the electron serving as a carrier can be improved. This configuration can be applied to the n-channel MOSFET.

Although the sidewalls of the dummy gate 21 are covered with the silicon nitride films 22 in the third embodiment, another insulating film may be used, instead. Furthermore, a good process can be employed even when no such a film is provided. Additionally, although the silicon substrate 12 is used in the third embodiment, another substrate may be employed which includes a channel region 13 in which stress needs to be induced.

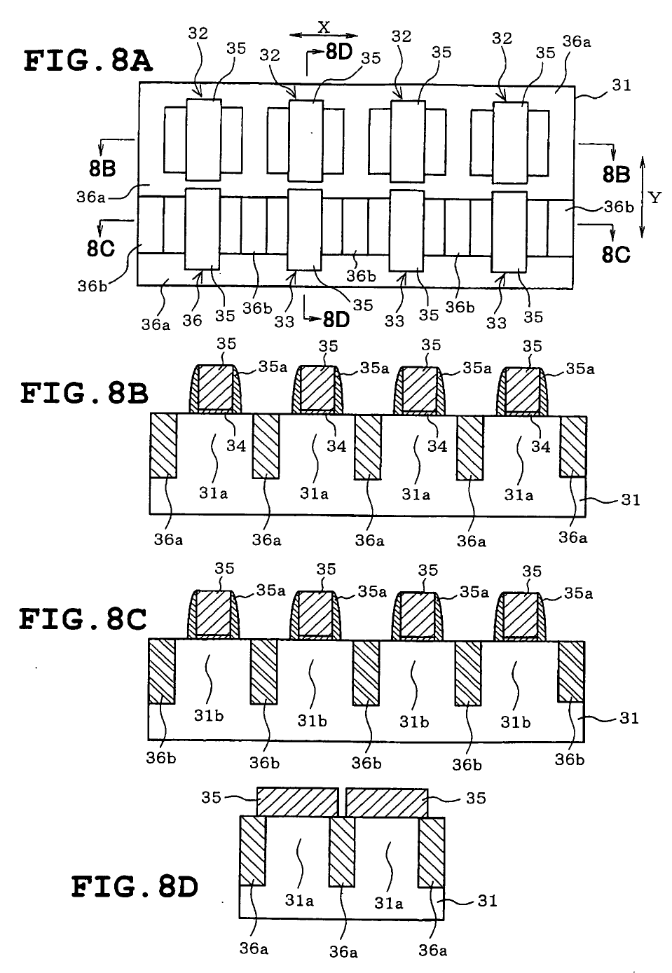

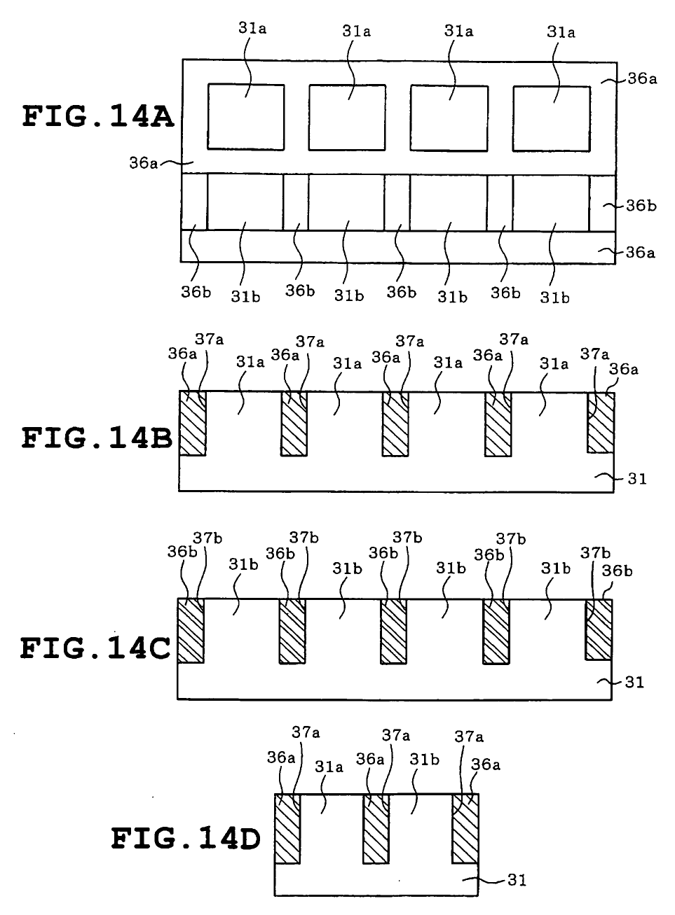

FIGS. 8A to 17 illustrate a fourth embodiment of the invention. The invention is applied to an integrated circuit of complementary metaloxide semicondictors (CMOS's). FIGS. 8A to 8D show a semiconductor device comprising, for example, four pairs of CMOS transistors. FIG. 8A is a schematic plan view of the semiconductor device and FIGS. 8B to 8D are sectional views taken along lines 8B-8B, 8C-8C and 8D-8D in FIG. 8A respectively.

On the silicon substrate 31 are formed four n-channel metal oxide semiconductor field effect transistors (hereinafter “n-MOSFET's”) 32 serving as complementary metal oxide semiconductor (CMOS) transistors and four p-channel MOSFET's (hereinafter “p-MOSFET's”) 33. The n-MOSFET's 32 and p-MOSFET's 33 are arranged in two rows extending in the X direction. Each pair of n-MOSFET 32 and p-MOSFET 33 constituting the CMOS transistor are arranged in the Y direction.

Each MOS transistor 32 and 33 includes a gate insulating film 34 formed on the silicon substrate 31 and a gate electrode 35 formed on the gate insulating film 34. Each gate electrode 35 has sidewalls on which spacers 35a are formed respectively. The n-MOSFET's 32 and p-MOSFET's 33 are formed in element formation regions 31a and 31b isolated by first and second shallow trench isolation (STI) structures 36a and 36b serving as element isolation regions respectively. The first STI structure 36a is formed in an outer periphery of each n-MOSFET 32 and in a lower side of each p-MOSFET 33 as viewed in FIG. 8A. An O₃-TEOS film serving as a first insulating film is buried in a trench of the first STI structure 36a. Furthermore, a second STI structure 36b is formed in the other sides of each p-MOSFET 33. A high density plasma TEOS (HDP-TEOS) film serving as a second insulating film is buried in a trench of the second STI structure 36b. In this case, the first insulating film or O₃-TEOS film is made from a material with shrink characteristics. The O₃-TEOS film shrinks after formation, thereby applying a tensile stress to the silicon substrate 31. Furthermore, the second insulating film or HDP-TEOS film is made form a material with expansivity. The HDP-TEOS film expands after formation, thereby applying a compressive stress to the silicon substrate 31.

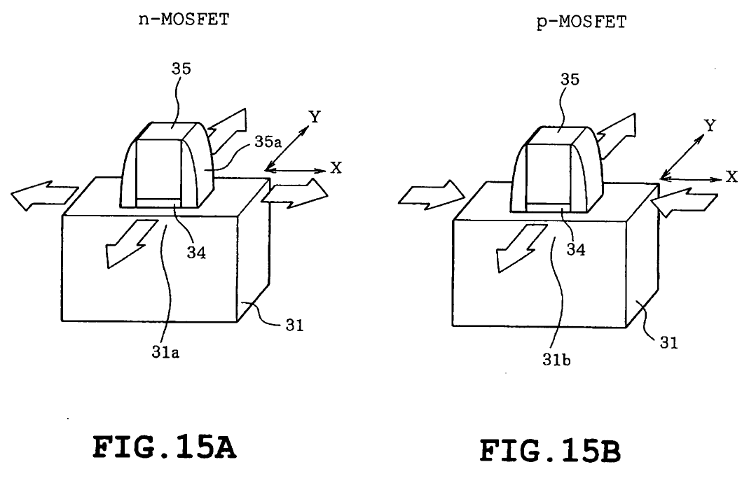

When the above-described configuration is employed, each element formation region 31a in which the n-MOSFET 32 is formed is subjected to the tensile stress applied by the first STI structure 36a provided in the outer periphery thereof. FIG. 15A schematically illustrates the state. As a result, the channel region of each element formation region 31a is also subjected to the tensile stress from all around, whereupon the mobility of electrons which are carriers of the n-MOSFET 32 is increased as compared with a case where the channel region is not subjected to stress, as known as a physical characteristic of silicon monocrystal. Moreover, since the tensile stress acts both in the direction of movement of carriers and in the direction perpendicular to the carrier movement direction, the mobility of electrons can be further improved as compared with the case where the tensile stress acts only in one direction.

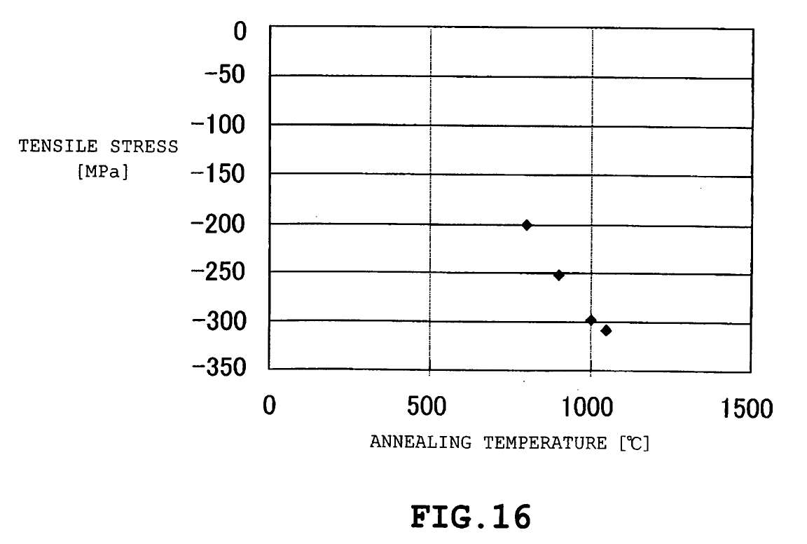

Furthermore, each element formation region 31b in which the p-MOSFET 33 is formed is subjected both to the tensile stress from the first STI structure 36a and to the compressive stress from the second STI structure 36b. FIG. 16B schematically shows the state. Accordingly, the channel region of each element formation region 31b is subjected both to the compressive stress in the direction of movement of holes serving as carriers and to the tensile stress. As a result, the mobility of the holes can be improved as compared with the conventional configuration in which the channel region is subjected only to the compressive stress.

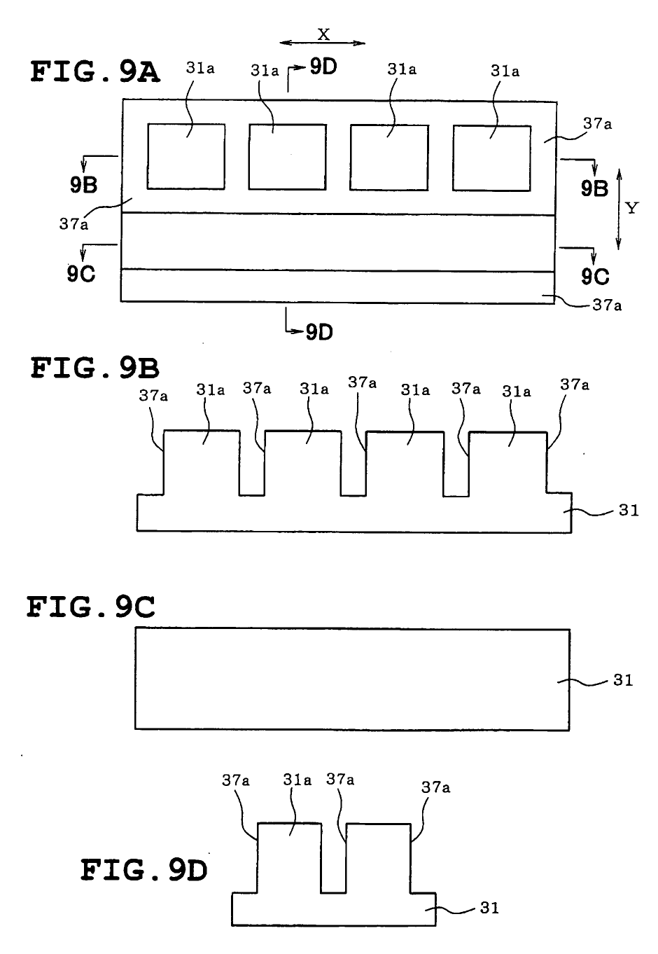

A fabricating process of the above configuration will now be described with reference to FIGS. 9A to 14D. A trench 37a serving as a first trench is formed in the silicon substrate 31 as shown in FIGS. 9A to 9D. The photolithography process is carried out to pattern the resist. In this case, the resist is patterned so that a part of the resist corresponding to the element formation region 31a of each n-MOSFET 32 is etched. The resist is further patterned so that an opposed side of the resist pattern in the Y direction corresponding to the element formation region 31b (not shown) of each p-MOSFET 33 is etched. Subsequently, openings of the resist are etched by a reactive ion etching (RIE) process, whereby the trench 37a is formed.

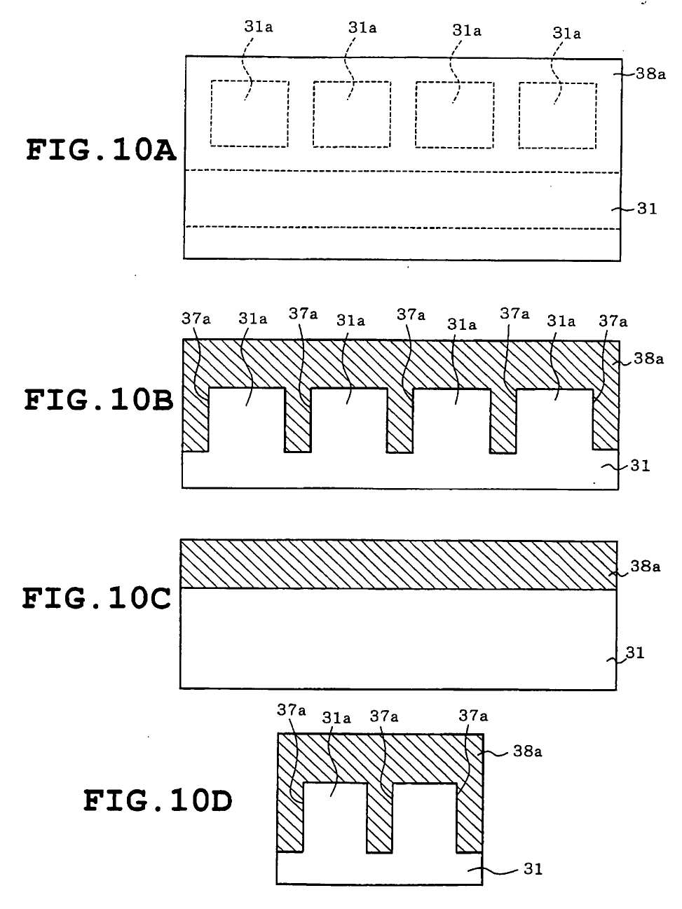

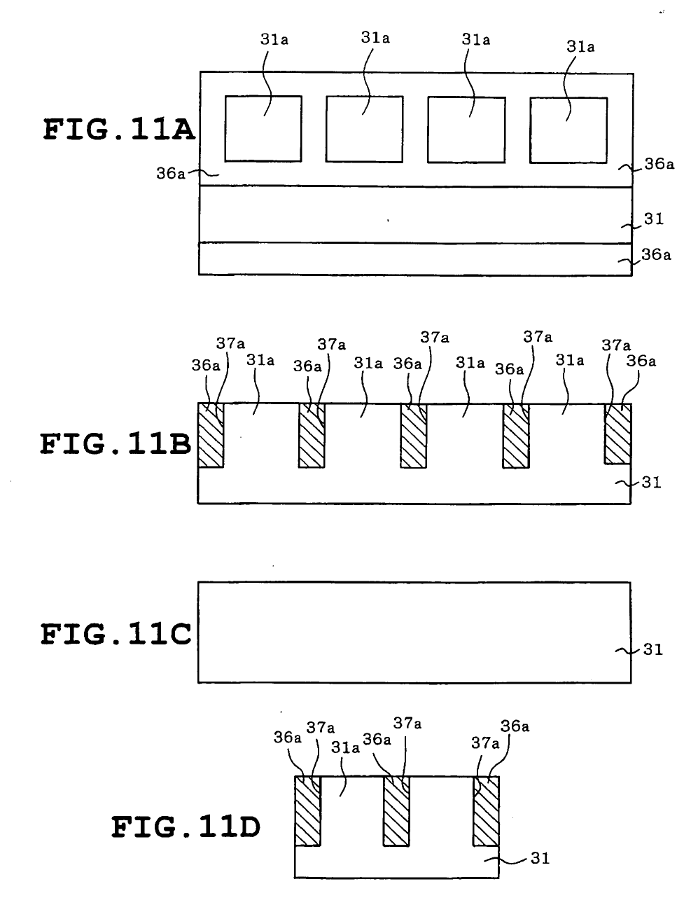

Next, a whole surface of the silicon substrate 31 is covered with an oxide film (hereinafter, “O₃-TEOS film”) 38a which is made from O₃-TEOS and serves as the first insulating film, as shown in FIGS. 10A to 10D. In this case, the conditions for fabrication of the O₃-TEOS film 38a include the temperature of the silicon substrate 31 in the device ranging from 400° C. to 450°, an internal pressure ranging 50 HPa to 300 HPa, supplied O₂ (oxygen gas) ranging from 0 cc to 200 cc, TEOS ranging from 500 cc to 1000 cc and O₃ (ozone gas) ranging from 5000 cc to 10000 cc). Subsequently, the chemical mechanical polishing (CMP) process is carried out to remove the O₃-TEOS film from the surface of the silicon substrate 31 so that the O₃-TEOS film 38a remains only in each trench 37a, as shown in FIGS. 11A to 11D. As a result, the first insulating film 36a is formed in each trench 37a.

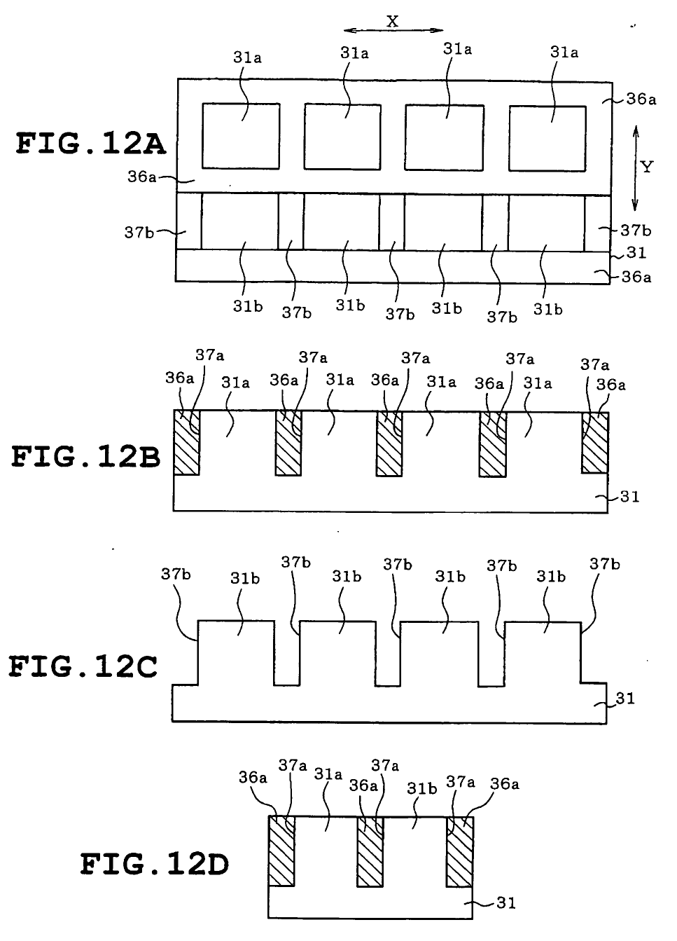

Successively, the buried first insulating film 36a is then annealed for adjustment of a tensile stress. In this case, an annealing temperature is changed in a range of 800° C. to 1050° C. such that a tensile stress the buried O₃-TEOS film 38a applies to the silicon substrate 31 can be changed from 0 to 250 MPa, as shown in FIG. 16. Next, the trench 37b serving as the second trench is formed in the silicon substrate 31 as shown in FIGS. 12A to 12D. The photolithography process is carried out in the same manner as described above so that sides opposed to each other in the X direction of the portion corresponding to the element formation region 31b of the p-MOSFET 33 or a remaining part at the step as shown in FIGS, 9A to 9D is etched thereby to be removed. The trenches 37b are formed with the above pattern serving as a mask.

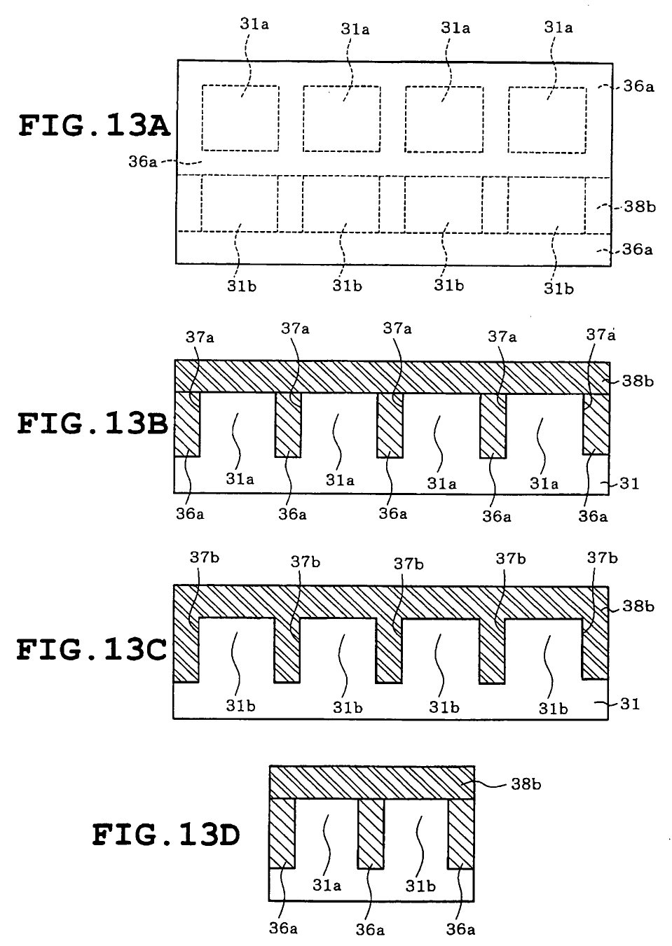

Next, an oxide film (HDP-TEOS film) made from HDP-TEOS and serving as the second insulating film buried in each trench 37b is formed on the whole surface of the silicon substrate as shown in FIGS. 13A to 13D. In this case, the conditions for fabrication of the HDP-TEOS film 38b include plasma power ranging from 4400 W to 8000 W, lead-in power ranging from 1200 W to 3000 W, a chamber pressure of about 50 mT, a flow rate of SiH₄ ranging from 50 sccm to 70 sccm and a flow rate of O₂ ranging from 80 sccm to 100 sccm.

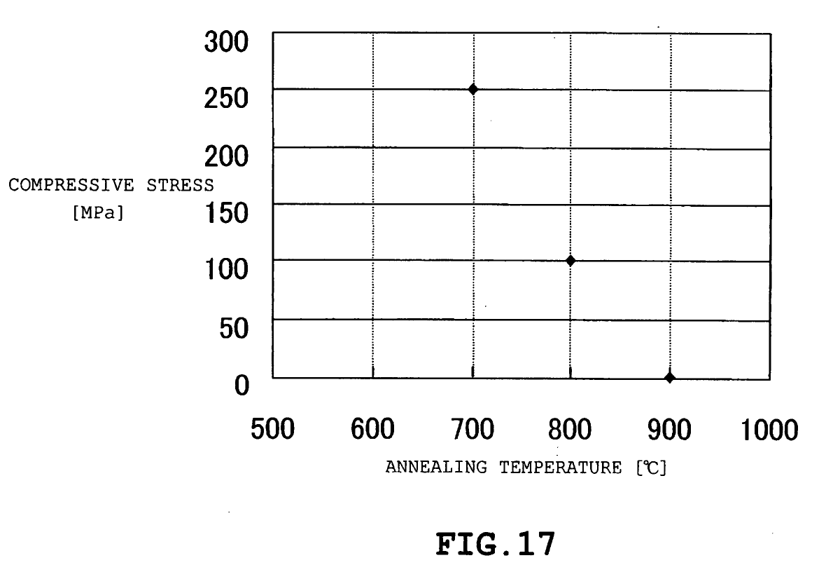

A CMP process is then carried out so that the HDP-TEOS film 38b on the surface of the silicon substrate 31 is removed and the HDP-TEOS film 38b remains only in each trench 37b. As a result, the first insulating film 36a is formed in each trench 37a and the second insulating film 36b is formed in each trench 37b. Successively, the buried second insulating film 36b is then annealed for adjustment of a tensile stress. In this case, an annealing temperature is changed in a range of 700° C. to 900° C. such that a tensile stress the buried O₃-TEOS film 38b applies to the silicon substrate 31 can be changed from 200 MPa to 300 MPa, as shown in FIG. 17. It is preferable that the annealing temperature of the second insulating film 36b be set so as to be lower than the annealing temperature of the first insulating film 36a. As a result, the first and second insulating films 36a and 36b can be set at respective stress magnitudes.

The gate insulating films 34 are formed in the element formation regions 31a and 31b through a general fabricating process which is similar to the fabricating process in the conventional technique. Film forming and annealing necessary for fabrication of transistors are carried out, whereby the configuration as shown in FIGS. 8A to 8D is obtained. Consequently, the source/drains regions and channel regions are formed in the element formation regions 31a and 31b.

In the fourth embodiment, the first STI structures 36a are formed so that tensile stresses are applied to the element formation region 31a of each n-MOSFET 32 from both X and Y directions. Furthermore, the first STI structures 36a are formed so that tensile stress is applied to the element formation region 31b of each p-MOSFET 33 from the Y direction and the second STI structure 36b is formed so that compressive stress is applied to the element formation region 31b of each p-MOSFET 33 from the X direction. Consequently, the mobility of electrons or holes serving as carriers can be improved in each of the MOSFET's 32 and 33. In this case, a larger stress is applied from both X and Y directions but not from either X or Y direction. As a result, the mobility can efficiently be improved without excessive application of stress in one direction relative to the silicon substrate 31.

Furthermore, the STI structures 36a and 36b are individually formed as the element isolation regions, and the first and second insulating films each producing either tensile or compressive stress are buried in the trenches of both STI structures 36a and 36b. Thus, the stresses can be applied to the channel region from two directions without any specific configuration.

The first and second STI structures 36a and 36b are annealed individually, and the annealing temperatures are set so that the annealing temperature for the first STI structure 36a is lower than that for the second STI structure. Consequently, since the magnitude of stress applied in each of the X and Y directions is adjusted, the stress can be set for values necessary for individual elements or devices.

The invention should not be limited to the above-described fourth embodiment. The fourth embodiment may be modified or expanded as follows. The CMOS is configured as a pair of p-MOSFET and n-MOSFET. However, the invention may be applied to a semiconductor device employing only the p-MOSFET 33 formed with a first element isolation region applying a tensile stress and a second element isolation region applying a compressive stress.

The first insulating film may be made from another material that can apply a tensile stress to the silicon substrate 31. Also, the second insulating film may be made from another material that can apply a compressive stress to the silicon substrate 31.

A desired stress may be obtained by adjustment of the annealing temperature. Furthermore, when a desired stress can be obtained from annealing at the same temperature for the materials of the first and second insulating films, annealing may be carried out once after formation of the first and second STI structures.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate having a surface layer;
a metal oxide semiconductor (MOS) transistor provided with two source/drain regions located at the surface layer side of the semiconductor substrate; and
a stress-inducing film formed so as to cover the source/drain regions of the MOS transistor, the stress-inducing film applying stress to a channel region formed between the source/drain regions and having an opening corresponding to an electrical connection region of the source/drain regions, the opening having a first dimension with respect to a propagation direction of carriers moving within the channel region of the MOS transistor and a second dimension with respect to a direction perpendicular to the propagation direction of the MOS transistor, the first dimension being larger than the second dimension.

2. The semiconductor device according to claim 1, wherein the stress-inducing film applies the stress to the channel region in a first direction in a case where the MOS transistor is of an n-channel type and the stress-inducing film applies the stress to the channel region in a second direction in a case where the MOS transistor is of a p-channel type, the first and second directions being opposed to each other.

3. The semiconductor device according to claim 1, wherein the stress-inducing film is a silicon nitride film.

4. A semiconductor device comprising:
a semiconductor substrate having a surface layer;
a metal oxide semiconductor (MOS) transistor provided with a gate electrode formed on the semiconductor substrate with a gate insulating film being interposed therebetween and two source/drain regions located at opposite sides of the gate electrode at the surface layer side of the semiconductor substrate; and
a stress-inducing film formed so as to cover the gate electrode of the MOS transistor, thereby applying stress to a channel region to be formed between the source/drain regions, the stress-inducing film having an opening formed in a part thereof corresponding to an electrical connection region of the gate electrode, the opening having a first dimension with respect to a propagation direction of a charge carrier moving within the channel region of the MOS transistor and a second dimension with respect to a direction perpendicular to the propagation direction of the MOS transistor, the first dimension being larger than the second dimension.

5. The semiconductor device according to claim 4, wherein the stress-inducing film applies the stress to the channel region in a first direction in a case where the MOS transistor is of an n-channel type and the stress-inducing film applies the stress to the channel region in a second direction in a case where the MOS transistor is of a p-channel type, the first and second directions being opposed to each other.

6. The semiconductor device according to claim 4, wherein the stress-inducing film is a silicon nitride film.

7. A semiconductor device comprising:
a semiconductor substrate having a surface;
a channel region formed on the semiconductor substrate and having an upper surface;
two source/drain regions formed on the semiconductor substrate with the channel region being interposed therebetween, each source/drain region being made from a semiconductor material having a lattice constant differing from the semiconductor substrate; and
a gate insulating film and a gate electrode each formed on the upper surface of the channel region, wherein the channel region is distributed so that strain due to stress the channel region receives from the source/drain region is largest at the surface side of the semiconductor substrate and becomes smaller in a direction of depth of the channel region.

8. The semiconductor device according to claim 7, wherein the semiconductor substrate is made from a material comprising silicon (Si) and each source/drain region is made from a material comprising silicon germanium (SiGe), and the channel region is configured so as to receive a compressive stress from each source/drain region.

9. The semiconductor device according to claim 7, wherein the semiconductor substrate is made from a material comprising silicon (Si) and each source/drain region is made from a material comprising silicon carbide (SiC), and the channel region is configured so as to receive a tensile stress from each source/drain region.

10. A method of fabricating a semiconductor device, comprising:
removing portions of a semiconductor substrate corresponding to source/drain regions to be formed at both sides of a channel region respectively;
burying a semiconductor material in portions resulting from removal of the portions corresponding to the source/drain regions, the semiconductor material having a lattice constant differing from the semiconductor substrate; and
forming a gate insulating film and a gate electrode on a surface of the channel forming region of the semiconductor substrate.

11. The method according to claim 10, wherein selective epitaxial growth is carried out in the burying step.

12. The method according to claim 10, wherein the semiconductor material buried in the source/drain regions is silicon germanium or silicon carbide when a silicon substrate is used as the semiconductor substrate.

13. A semiconductor device comprising:
a semiconductor substrate;
an element formation region formed on the semiconductor substrate so as to include a channel region serving as a propagation path of a carrier; and
a gate electrode formed on a gate insulating film further formed on the channel region, wherein the element formation region is formed so that the channel region receives, from an outer periphery of the element formation region, a tensile stress in a direction perpendicular to the propagation path of the carrier and a compressive stress in a direction of the propagation path.

14. The semiconductor device according to claim 13, further comprising an element isolation region formed around the element formation region of the semiconductor substrate and including a first insulating film buried in the element isolation region so as to apply the tensile stress to the channel region in the direction perpendicular to the propagation path of the carrier and a second insulating film buried in the element isolation region so as to apply the compressive stress to the channel region in the direction in the direction of the propagation path.

15. The semiconductor device according to claim 14, wherein the first insulating film is made from a material which contracts after formation thereof and the second insulating film is made from a material which expands after formation thereof.

16. The semiconductor device according to claim 15, wherein the first insulating film is an O₃-tetraethyl orthosilicate (TEOS) film.

17. The semiconductor device according to claim 15, wherein the second insulating film is a high density plasma tetraethyl orthosilicate (HDP-TEOS) film.

18. A semiconductor device comprising:
a semiconductor substrate;
a first element formation region formed on the semiconductor substrate and including a first channel region which serves as a propagation path for electrons as carriers;
a second element formation region formed on the semiconductor substrate and including a second channel region which serves as a propagation path for holes as the carriers, the second element formation region being adjacent to the first element formation region so that the propagation path of the carriers of the second formation region is parallel to the propagation path of the carrier of the first formation region; and
a gate electrode formed on a gate insulating film further formed on upper parts of the first and second channel regions, wherein the first element formation region is formed so that the channel region receives, from an outer periphery of the element formation region, a tensile stress both in a direction of the propagation path of the electrons and in a direction perpendicular to the propagation path of the carriers, and the second element formation region is formed so that the channel region receives, from an outer periphery of the element formation region, a compressive stress in a direction of the propagation path of the holes.

19. The semiconductor device according to claim 18, further comprising an element isolation region formed around the first and second element formation regions of the semiconductor substrate and including a first insulating film buried in the element isolation region so as to apply the tensile stress to the channel region in a first direction of the propagation path for electrons as the carriers of the first channel region, a second direction perpendicular to the first direction and a third direction perpendicular to the propagation path for the holes as the carriers of the second channel region, and a second insulating film applying a compressive stress in the direction of the propagation path for the holes as carriers in the second channel region.

20. A method of fabricating a semiconductor device, comprising:
forming a first trench in first sides of a semiconductor substrate opposed to each other with an element formation region being interposed therebetween;
burying a first insulating film in the first trench, the first insulating film applying a tensile stress to the element formation region;
forming a second trench in second sides of the semiconductor substrate opposed to each other with the element formation region being interposed therebetween;
burying a second insulating film in the second trench, the second insulating film applying compressive stress to the element formation region;
forming a channel region and source/drain regions so that a direction in which the element formation region receives compressive stress from the second trench is identical with a direction of propagation path of a carrier; and
forming a gate electrode on a gate insulating film formed on an upper part of the channel region.

21. The method according to claim 20, wherein in the first insulating film burying step, a temperature in a thermal treatment carried out after the burying process is adjusted, thereby adjusting a magnitude of the tensile stress applied to the element formation region.

22. The method according to claim 20, wherein in the second insulating film burying step, a temperature in a thermal treatment carried out after the burying process is adjusted, thereby adjusting a magnitude of the compressive stress applied to the element formation region.

23. A method of fabricating a semiconductor device, comprising:
forming a first trench in a peripheral side of a first element formation region of a semiconductor substrate and a pair of sides opposed to a side adjacent to the first element formation region of a second element formation region;
burying a first insulating film in the first trench, the first insulating film applying tensile stress to the first and second element formation regions;
forming a second trench in sides which are opposed to each other with the second element formation region being interposed therebetween and differs from the sides in which the first trench is formed;
burying a second insulating film in the second trench, the second insulating film applying a compressive stress to the second element formation region;
forming a channel region and source/drain regions in the first and second element formation regions respectively so that a direction in which the second element formation region receives the compressive stress from the second trench is identical with a direction of propagation path of a carrier; and
forming a gate electrode on a gate insulating film further formed on an upper part of the channel region.
